(19) United States
(12) Patent Application Publication
(10) Pub. No.: US 2009/0276685 A1
(43) Pub. Date: Nov. 5, 2009

(54) DATA DECODING APPARATUS, MAGNETIC DISK APPARATUS, AND DATA DECODING METHOD

(75) Inventor: Kenji Yoshida, Akishima-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/345,578

(22) Filed: Dec. 29, 2008

(30) Foreign Application Priority Data
Apr. 30, 2008 (JP) 2008-118796

(51) Int. Cl. H03M 13/05; G06F 11/07

(52) U.S. Cl. 714/769; 714/752; 714/E11.021

(57) ABSTRACT

A data decoding apparatus has: a check matrix including a submatrix which indicates a parity restriction and used for LDPC decoding; a first decoding module configured to decode data by using the submatrix so that the parity restriction is satisfied; and a second decoding module configured to LDPC-decode the decoded data by using the check matrix.

### CROSS-REFERENCE TO RELATED APPLICATIONS

This application is based upon and claims the benefit of priority from the prior Japanese Patent Application No. 2008-118796, filed on Apr. 30, 2008; the entire contents of which are incorporated herein by reference.

### BACKGROUND OF THE INVENTION

1. Field of the Invention

The present invention relates to a data decoding apparatus, a magnetic disk apparatus, and a data decoding method to LDPC-decode data.

2. Description of the Related Art

An LDPC (Low-Density Parity-Check) code attracts attention as an error correction technology. The LDPC code is a linear code limited so that a number of “1”s included in a check matrix is small (is of low-density). Limiting the number of “1”s included in the check matrix enables repeated decoding called a reliability propagation method. Further, making a code length of the LDPC code large and have randomness enables error correction with accuracy higher than a conventional error correction code (for example, a hamming code and Read-Solomon code).

Meanwhile, for error correction, Viterbi decoding is used. In the Viterbi decoding, convolution-coded data (coded data) is decoded. Decoded data which is most likely (with maximum likelihood) is estimated and that coded data is decoded to original data. Here, for the Viterbi decoding, a technology to check a parity is disclosed (see “A 450 Mbit/s parallel read/write channel with parity check and 16-sate time variant Viterbi” Custom Integrated Circuits Conference, 2000. CICC. Proceedings of the IEEE 2000, Volume, Issue, 2000 Page(s) 319-322).

### BRIEF SUMMARY OF THE INVENTION

The afore-mentioned literature does not disclose a technology to use LDPC decoding in combination with a parity restriction.

An object of the present invention is to provide a data decoding apparatus, a magnetic disk apparatus, and a data decoding method to correct data by using both the LDPC decoding and decoding using the parity restriction.

A data decoding apparatus according to an embodiment of the present invention has: a check matrix including a submatrix which indicates a parity restriction and used for LDPC decoding; a first decoding module configured to decode data by using the submatrix so that the parity restriction is satisfied; and a second decoding module configured to LDPC-decode the decoded data by using the check matrix.

A magnetic disk apparatus according to an embodiment of the present invention has: a check matrix including a submatrix which indicates a parity restriction and used for LDPC decoding; a reproducing module configured to reproduce data from a magnetic disk; a first decoding module configured to decode the reproduced data by using the submatrix so that the parity restriction is satisfied; and a second decoding module configured to LDPC-decode the decoded data by using the check matrix.

A data decoding method according to an embodiment of the present invention has: decoding data by using a submatrix of a check matrix including the submatrix which indicates a parity restriction and used for LDPC decoding so that the parity restriction is satisfied; and LDPC-decoding the decoded data by using the check matrix.

### BRIEF DESCRIPTION OF THE DRAWINGS

FIG. 1 is a block diagram showing an information recording/reproducing system 100 according to an embodiment.

FIG. 2A is a block diagram showing an example of an internal constitution of a coding module 122.

FIG. 2B is a block diagram showing an example of an internal constitution of a decoding module 125.

FIG. 3A is a schematic view showing a check matrix H1 according to an embodiment.

FIG. 3B is a schematic view showing a check matrix H2 according to an embodiment.

FIG. 3C is a schematic view showing a check matrix H0 according to a comparison example.

### DETAILED DESCRIPTION OF THE INVENTION

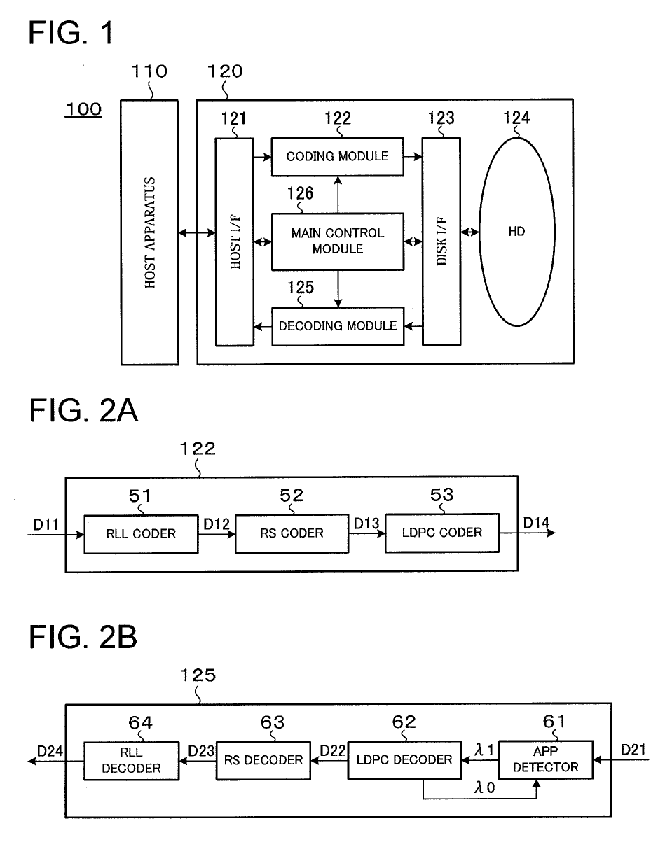

Hereinafter, an embodiment of the present invention will be described in detail with reference to the drawings. FIG. 1 is a block diagram showing an information recording/reproducing system 100 according to an embodiment. The information recording/reproducing system 100 has a host apparatus 110 and an HDD (hard disk drive) 120.

The host apparatus 110 is, for example, a PC (personal computer). This host apparatus 110 writes and read information to/from the HDD 120.

The HDD 120 is an information recording/reproducing apparatus and corresponds to a magnetic disk apparatus (data reproducing apparatus). The HDD 120 has a host I/F (interface) 121, a coding module 122, a disk I/F (interface) 123, an HD (hard disk) 124, a decoding module 125, and a main control module 126.

The host I/F 121 is an interface to give/receive information between the host apparatus 110 and the HDD 120.

The coding module 122 codes (RLL-codes, RS-codes, LDPC-codes) data inputted from the host apparatus 110. Details thereof will be described later.

The disk I/F 123 writes and reads the data coded in the coding module 122 to/from the HD 124. The HD 124 is a magnetic recording medium (a type of recording medium) from/to which data is read/written by the disk I/F 123.

The decoding module 125 decodes (LDPC-decodes, RS-decodes, RLL-decodes) the data read from the HD 124 by the disk I/F 123. Details thereof will be described later.

The main control module 126 has a CPU (central processing module) built-in and integrally controls an operation of the HDD 120. The main control module 126 controls the coding module 122 and the disk I/F 123 to write data to the HD 124 by a write request command from the host apparatus 110. Further, the main control module 126 controls the disk I/F 123 and the decoding module 125 to read data from the HD 124 by a read request command from the host apparatus 110.

### (Details of Coding Module 122 and Decoding Module 125)

Hereinafter, the details of the coding module 122 and the decoding module 125 will be described. FIG. 2A and FIG. 2B are block diagrams showing examples of internal constitutions of the coding module 122 and the decoding module 125, respectively.

The coding module 122 has an RLL (Run Length Limited) coder 51, an RS (Reed Solomon) coder 52, and an LDPC (Low-Density Parity-Check) coder 53. The decoding module 125 has an APP (A Posteriori Probability) detector 61, an LDPC decoder 62, an RS decoder 63, and an RLL decoder 64. The data inputted to the coding module 122 from the host apparatus 110 via the host I/F 121 is RLL-coded, RS-coded, and LDPC-coded in sequence, and then written to the HD 124. The data inputted to the decoding module 125 from the HD 124 via the disk I/F 123 is Viterbi-decoded, LDPC-decoded, RS-decoded, and RLL -decoded in sequence, and then outputted to the host apparatus 110.

A generation matrix G and a check matrix H are used for LDPC-coding and LDPC-decoding. An LDPC code is a linear block code and defined by the check matrix H. The check matrix H according to the present embodiment is used for both the LDPC-decoding and decoding using a parity restriction.

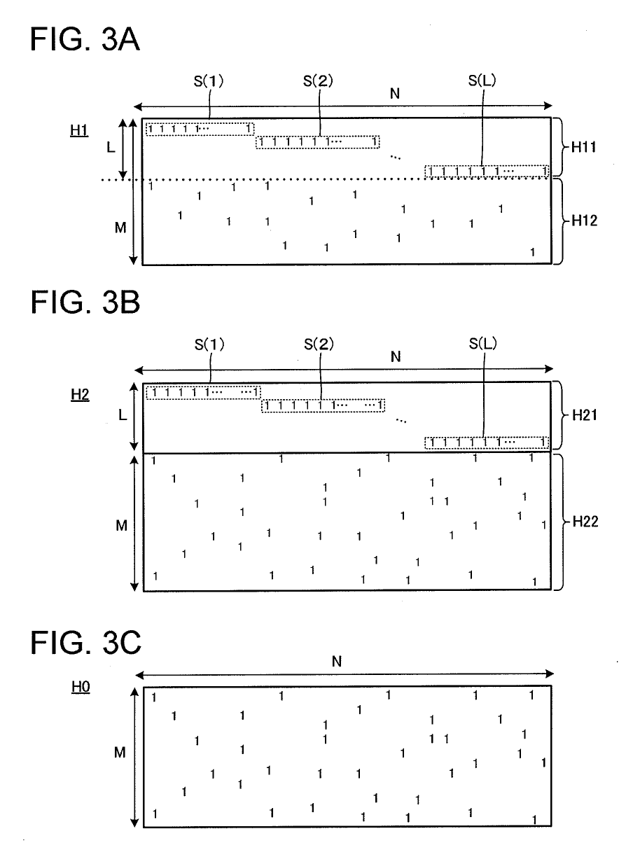

FIG. 3A and FIG. 3B are schematic views showing examples (check matrixes H1, H2) of the check matrix H according to the present embodiment. FIG. 3C is a schematic view showing an example (check matrix H0) of a normal check matrix H. It should be noted that only “1”s in the matrix are shown and “0”s are omitted to be written in FIG. 3A to FIG. 3C.

First, the normal check matrix Ho will be described. The check matrix H0 is used for only the LDPC-decoding. When a code length is N and a number of parity restrictions is M, the check matrix H0 becomes an M-row N-column matrix.

As shown in the following formula (1), by LDPC-coding a data column D1 by a generation matrix G0, an LDPC-coded data column D2 is generated.

D2=D1·G0 formula (1)

The data column D1 is a K-dimension vector, and the generation matrix G0 is a K-row N-column matrix. The data column D2 is equivalent to what is made by adding a parity column of a parity length M to the data column D1 of a data length K, and has a code length N (=K+M).

The data column D2 subjected to LDPC has a relation represented by the following formula (2) with the check matrix H0.

H0·D2^{T}=0 formula (2)

Here, the data column D2 is an N-dimension vector, and “0” is an N-dimension zero vector. Further, T means transposition (exchange of the row and the column) of the data column D2. In other words, a left side of the formula (2) means LDPC (Low-Density Parity-Check) to the data column D2. When the formula (2) is satisfied, it means that an error is not found in the data column D2 by the LDPC.

The generation matrix G0 and the check matrix H0 have a relation represented by the following formula (3).

H0·G0^{T}=0 formula (3)

In the formula (3), a “0” indicates an M-row K-column zero matrix.

As already stated, the check matrix H1 is used for both the LDPC-decoding and the decoding using the parity restriction. The entire check matrix H1 is used for the low-density parity-check (LDPC). The check matrix H1 is divided into submatrixes H11, H12. In the submatrix H11, is and 0s are continually disposed in a row direction and used for both the LDPC-decoding and the decoding using the parity restriction. Meanwhile, in the submatrix H12, is are discretely disposed in a row direction and are used for only the LDPC-decoding.

Vectors S(1) to S(L) having continual “1”s as elements are disposed in each row in the submatrix H11. For example, the vector S(1) disposed in a first row has continual “1”s from first column to a N₁-th column as elements. A vector S (i) disposed in an I-th row has continual “1”s from an (N₍ᵢ₋₁₎+1)-th column to an Nᵢ-th column as elements. In other words, the vector S(i) is disposed in different columns per row. As a result, each column of the submatrix H11 includes only one “1”. It should be noted that match/variance of a number of “1”s in the respective vectors S(1) to S(L) itself is not a problem in particular. For example, a number of elements of each vector S(i) can be the same. Variance in the number of elements of each vector S(i) is also allowed.

The check matrix H1 can be created by transforming the check matrix H0. Replacement (exchange) between the columns of the check matrix H0 enables transformation so that “1”s continue in the row direction. As an example thereof, a QC (quasi-cyclic) LDPC code can be cited. A check matrix H of the QCLDPC code is constituted by connecting matrixes made by cyclic-shifting module matrixes vertically and horizontally. If the check matrix H0 is a check matrix of the QCLDPC code, transformation to the check matrix H1 can be performed by column replacement of the check matrix H0.

The check matrix H2 is divided into submatrixes H21, H22. The submatrix H22 is the same as the check matrix H0. In other words, the check matrix H2 is equivalent to what is made by adding the submatrix H21 to the check matrix H1. In this example, the submatrix H21 is the same as the submatrix H11. However, the submatrix H 21 and the submatrix H11 are not necessarily required be the same.

The check matrix H2 is also used for both the LDPC decoding and the decoding using the parity restriction. The submatrix H21 is used only for the decoding using the parity restriction. The submatrix H22 is used only for the LDPC decoding.

Various kinds of parity restrictions can be added to the submatrixes H11, H21. In particular, the submatrix H21 is released from a limitation due to the original check matrix H0 and a parity restriction can be added accordingly. As such a parity restriction, for example, 80/81 coding can be cited. This coding is to add one-bit parity bit per 80 bits and a data series always satisfying the parity per unit of 81 bits is generated. In this case, “1”s are continually disposed by 81 bits in a lateral direction (row direction) of the submatrixes H11, H21.

The check matrixes H1, H2 are stored in the HDD 120 (for example, the coding module 122, the decoding module 125). However, the check matrixes H1, H2 are not necessarily required to be always stored. It is possible to generate the check matrixes H1, H2 as necessary.

The RLL coder 51 run-length codes an inputted data column D11 and then outputs as a data column D12. The run-length coding is a type of run length limit processing (for example, a processing to make a succession of “0”s of equal to or more than a predetermined number not occur).

The RS coder 52 calculates an ECC (Error Correcting Code) based on an RS (Reed Solomon) code and adds it to the run-length coded data column D12, whereby a data column D13 is generated.

The LDPC coder 53 LDPC-codes the data column D13 inputted from the RS coder 52 and generates a data column D14. The data column D14 is written to the HD 124 by the disk I/F 123.

As already stated, the LDPC coder 53 generates the LDPC-coded data column D14 by computation of the data column D13 and the generation matrix G (see formula (1)). On this occasion, as the generation matrix G, for example, there is used a generation matrix G1 corresponding to the check matrix H1 and a generation matrix G2 corresponding to the check matrix H2. The data column D13 is LDPC-coded, and the parity restriction indicated in the submatrixes H11, H21 is added. It should be noted that relations between the check matrix H1 and the generation matrix G1 and between the check matrix H2 and the generation matrix G2 are represented according to the formula (3).

Here, an LDPC code to which a parity restriction is applied is able to be generated without directly using the generation matrix G2. In this case, an LDPC coder 53 can be constituted with a combination of a normal LDPC coder and a parity coder. Hereinafter, details thereof will be described.

First, a data column D13 is LDPC-coded by using a generation matrix G22 corresponding to a check matrix H22 (processing in the normal LDPC coder). Next, the LDPC-coded data column D13′ is parity-coded based on a parity restriction indicated by a check matrix H21 (processing in the parity coder). In other words, a parity bit (81st bit in a case of the 80/81 coder) is applied to the data column D13′.

Here, an “1” is not allowed to exist in a column corresponding to the parity bit in the check matrix H22 (if an “1” is disposed in this column, “0” and “1” are fixed by LDPC-coding (computation in the generation matrix G22, and the parity bit cannot be inserted). Therefore, a column whose elements are all “0”s exists in the check matrix H22.

A matrix from which such a column is removed is considered. In other words, there is assumed a check matrix H22′ in which a column whose elements are all “0”s is excluded from the check matrix H22. Then, this check matrix H22′ has no restriction in particular about a position of an “1” and can be constituted freely. An LDPC code to which a parity restriction is applied can be generated by using a generation matrix G22′ corresponding to the check matrix H22′. In other words, a data column is LDPC-coded by using the generation matrix G22′, and further, a parity bit is inserted to the LDPC-coded data column. Data column D and check matrix H2 outputted after such two-stage coding satisfy a relation represented by the formula (2).

The data written to the HD 124 is read by the disk I/F 123. Here, it is assumed that the data column D21 is read. To the data column D21 is added a noise (for example, a burst noise), due to an error or the like at a writing/reading time.

Here, a signal recorded/reproduced in/from the HD 124 has a PR (Partial Response) characteristic. This PR characteristic derives from a characteristic of recording/reproducing in/from the HD 124, that is, a characteristic that a bit recorded immediately before influences a reproduction signal (waveform interference). In other words, the PR characteristic is a type of characteristic specific to a recording/reproducing series. It should be noted that various classes such as PR1, PR2, and PR4 exist in the PR characteristic in correspondence with a depth or degree of the interference.

This method of decoding by using the PR characteristic is known as a PRML (Partial Response Maximum Likelihood) method. In an APP detector 61, a signal having the PR characteristic can be decoded by using the PRML method. In a case that the parity restriction has been applied to a recorded/reproduced signal, this parity restriction can be used in a process of decoding (for example, a later-described PRML-Viterbi decoding) by this PRML method in the APP detector 61. In this case, this parity restriction is reflected in the submatrix H11 or H21.

The APP detector 61 functions as a first decoding part decoding data so that the parity restriction is satisfied. The APP detector 61 outputs a probability that each bit of the data column D21 is “0” and a probability that each bit of the data column D21 is “1” (likelihood, a posterior probability λ) by using, for example, the Viterbi decoding (soft decision output). In the APP detector 61, Viterivi decoding by using the PRML method in conjunction therewith is possible (PRML-Viterbi decoding).

On this occasion, accuracy of likelihood can be improved by using the parity restriction of the data column D21. For example, the accuracy of likelihood can be improved by using a parity restriction by time-variant Viterbi decoding. The time-variant Viterbi decoding is a type of Viterbi decoding. In the time-variant Viterbi decoding, transition of a state in the Viterbi decoding is limited at a bit position equivalent to a parity bit (the most right “1” among plurality of “1”s continually disposed in each row of the submatrix H11 or H21) so that the parity restriction is satisfied.

Further, a method other than the time-variant Viterbi can be used. For example, in a case that a data column outputted by the normal Viterbi decoding does not satisfy the parity restriction, the data column can be replaced so that the parity restriction is satisfied.

In these methods, which of “0” and “1” each bit of the data column D21 is is estimated by using that a reproduced signal (data column D21) satisfies the parity restriction, and how likely it is is outputted as likelihood. In order to output this likelihood, for example, SOVA (Soft Output Viterbi Algorithm) decoding is used in the Viterbi decoding. In the APP detector 61, both this SOVA decoding and the aforementioned time-variant Viterbi decoding can be performed.

Hereinafter, a case that the time-variant Viterbi decoding and the SOLVA decoding are used will be concretely described.

The APP detector 61 obtains transition which has a high probability as a data column D21 among paths of a state transition diagram called a trellis by using the parity restriction (for example, characteristic complying with the PR series) of the data column 21. On this occasion, a signal level per bit of the data column D21 and prior information λ0 are used. The prior information λ0 indicates a probability of being “0” and a probability of being “1” per bit of the data column D21. It is assumed that the probabilities of being “0” and being “1” are equal in first prior information λ0. However, if it is found that the probabilities of “0” and “1” are unequal, those probabilities can be used as the first prior information.

Here, the APP detector 61 holds twice a state number of normal trellises. It is because a state (two states) of the parity at each hour is required to be indicated in order to perform the time-variant Vitrebi decoding. However, at a position equivalent to the parity bit, it is made so that only a state transition satisfying the parity restriction occurs. In this way, the path of the state transition at a position equivalent to the parity bit is different from the path at a position other than the parity bit.

Based on a level of the reproduction signal (data column D21) and the prior information λ0, a state transition with the highest probability is obtained among state transitions depicted on the trellises varying in correspondence with such a bit position. When the state transition with the highest probability is determined, which one of “0” and “1” each bit of the data column D21 is is determined in correspondence therewith. On this occasion, from a difference between the state transition path selected finally and the probability of a path discarded after comparison with that path, probabilities of “0” and “1” of each bit of the data column D 21 are obtained. The APP detector 61 outputs the probability of being “0” and the probability of being “1” as an APP (A Posteriori Probability) λ1. In general, the probability of being “0” and the probability of being “1” are frequently indicated in a form of log likelihood ratio (LLR). The log likelihood ratio is obtained by dividing a probability P1 that data becomes “1” by a probability P0 that the data becomes “0” and then logarithmizing a quotient.

The LDPC decoder 62 functions as a second decoding part LDPC-decoding the data decoded in the APP detector 61. The LDPC decoder 62 performs the LDPC decoding by a reliability propagation calculation based on the a posteriori probability B1 inputted from the APP detector 61. The a posteriori probability A1 from the APP detector 61 is inputted to the LDPC decoder 62 as an a posteriori probability λ2 for the LDPC decoder 62.

The LDPC decoder 62 calculates a tentative judgment series (data series tentatively judged) D22′ by a repetition calculation based on a reliability propagation method. In this repetition calculation, the inputted a posteriori probability λ2 is propagated along a branch of a graph based on the parity restriction indicated in the check matrix H, and the probability is renewed.

Further, the LDPC decoder 62 judges whether or not the LDPC decoding is successful based on whether or not the relation represented by the formula (2) is established between the tentative judgment series D22′ and the check matrix H1 (or H2). If the relation indicated by the formula (2) is established, it is judged that the LDPC decoding is successful, and the tentative judgment series D22′ is outputted as a decoding series D22 from the LDPC decoder 62 to the RS decoder 63.

There is a possibility that the tentative judgment series D22′ with which the relation represented by the formula (2) is established cannot be obtained even if the repetition calculation based on the reliability propagation method is performed a predetermined number of times. In this case, decoding in the APP detector 61 is performed again. On this occasion, a renewed probability (a posteriori probability λ3) which is held in the LDPC decoder 62 is used as the prior probability λ0 of the APP detector.

Processings in the APP detector 61 and the LDPC decoder 62 are performed repeatedly. As a result of decoding based on the parity restriction in the APP detector 61, a number of repetitions of the processings in the APP detector 61 and the LDPC decoder 62 is decreased. If the decoding in the LDPC decoder 62 is successful, the decoding series D22 is outputted from the LDPC decoder 62. Meanwhile, if decoding is not successful after a predetermined times of repetitions of decoding, the last tentative judgment series D22′ is outputted as the decoding series D22.

The RS decoder 63 error-corrects the data column D22 outputted from the LDPC decoder 62 by using decoding algorithm of an RS (Reed Solomon) code, and generates a data series D63. The RLL decoder 64 run-length decodes the data column D23 outputted from the RS decoder 63 and outputs as a data column D24. The data column D24 is outputted to the host apparatus 110 via the host I/F 121.

As stated above, the present embodiment enjoys the following advantages.

In both the LDPC decoding and the Viterbi decoding, decoding by using the check matrixes H1, H2 (including the submatrixes H11, H21 which indicate the parity restrictions) becomes possible. In other words, in decoding, a parity decoding is effectively used.

Errors of the data series outputted from the Viterbi decoder (APP detector 61) are decreased. As a result, improvement of a convergence at a decoding time becomes possible.

The bit number of the check matrix H2 is the same as the bit number of the original check matrix H0, so that there is no increase in redundancy bit.

### Other Embodiments

The present invention is not limited to the above-described embodiment, but can be realized by modifying components without departing from the scope and spirit of the invention in an implementation phase. Further, by an appropriate combination of a plurality of components disclosed in the above-described embodiment, various inventions can be made. For example, some of the components may be deleted from the whole components shown in the embodiment. Further, the components in different embodiments can be appropriately combined.

What is claimed is:

1. A data decoding apparatus, comprising:
a check matrix configured for use in a low-density parity-check (LDPC) decoding process, the check matrix comprising a submatrix indicative of a parity restriction;
a first decoding module configured to decode data at least in part by using the submatrix so that the parity restriction is satisfied; and
a second decoding module configured to LDPC-decode the decoded data at least in part by using the check matrix.

2. The data decoding apparatus of claim 1, wherein the first decoding module is configured to decode data from, a reproduction signal at least in part by using a characteristic specific to a recording/reproducing series, and wherein the decoded data satisfies the parity restriction.

3. The data decoding apparatus of claim 1, wherein the submatrix is indicative of a plurality of parity restrictions; and wherein the first decoding module is configured to decode the data so that the plurality of parity restrictions are satisfied.

4. The data decoding apparatus of claim 3, wherein each row of the submatrix corresponds to one of the plurality of parity restrictions.

5. The data decoding apparatus of claim 4, wherein each row of the submatrix comprises one or more “1”s disposed continually in columns different from other rows of the submatrix.

6. A magnetic disk apparatus, comprising:
a check matrix configured for use in a low-density parity-check (LDPC) decoding process, the check matrix comprising a submatrix indicative of a parity restriction;
a reproducing module configured to reproduce data from a magnetic disk;
a first decoding module configured to decode the reproduced data at least in part by using the submatrix so that the parity restriction is satisfied; and
a second decoding module configured to LDPC-decode the decoded data at least in part by using the check matrix.

7. The magnetic disk apparatus of claim 6, wherein the first decoding module is configured to decode data from a reproduction signal at least in part by using a characteristic specific to a recording/reproducing series, and wherein the decoded data satisfies the parity restriction.

8. The magnetic disk apparatus of claim 6, wherein the submatrix is indicative of a plurality of parity restrictions; and wherein the first decoding module is configured to decode the data so that the plurality of parity restrictions are satisfied.

9. The magnetic disk apparatus of claim 8, wherein each row of the submatrix corresponds to one of the plurality of parity restrictions.

10. The magnetic disk apparatus of claim 9, wherein each row of the submatrix comprises one or more “1”s disposed continually in columns different from other rows of the submatrix.

11. A data decoding method, comprising:
decoding data at least in part by using a submatrix of a check matrix, the check matrix configured for use in a low-density parity-check (LDPC) decoding process, the submatrix being indicative of a parity restriction, the step of decoding data comprising decoding data so that the parity restriction is satisfied; and
LDPC-decoding the decoded data at least in part by using the check matrix.

12. The data decoding method of claim 11, wherein the data is decoded from a reproduction signal at least in part by using a characteristic specific to a recording/reproducing series and wherein the decoded data satisfies the parity restriction.

13. The data decoding method of claim 11, wherein the submatrix is indicative of a plurality of parity restrictions; and wherein the step of decoding data comprises decoding data so that the plurality of parity restrictions are satisfied.

14. The data decoding method of claim 13, wherein each row of the submatrix corresponds to one of the plurality of parity restrictions.

15. The data decoding method of claim 14, wherein each row of the submatrix comprises one or more “1”s disposed continually in columns different from other rows of the submatrix.
